(19) United States
(12) Patent Application Publication
(10) Pub. No.: US 2016/0126394 A1
(43) Pub. Date: May 5, 2016

(54) PHOTOVOLTAIC CELL AND METHOD FOR MANUFACTURING SUCH A PHOTOVOLTAIC CELL

(71) Applicant: STICHTING ENERGIEONDERZOEK CENTRUM NEDERLAND, Petten (NL)

(72) Inventors: Ingrid Gerdina ROMIJN, Petten (NL); John ANKER, Petten (NL); Desislava Simeonova SAYNOVA, Petten (NL); Antonius Radboud BURGERS, Petten (NL); Martien KOPPES, Petten (NL); Astrid GUTJAHR, Petten (NL)

(21) Appl. No.: 14/896,180

(22) PCT Filed: Jun. 6, 2014
(86) PCT No.: PCT/NL2014/050364

§ 371 Date: Dec. 4, 2015

(30) Foreign Application Priority Data
Jun. 7, 2013 (NL) 2010941

(51) Int. Cl. H01L 31/065; H01L 31/068; H01L 31/18; H01L 31/0236

(52) U.S. Cl. CPC H01L 31/065; H01L 31/02363; H01L 31/0682; H01L 31/1804

(57) ABSTRACT

A photovoltaic cell includes a semiconductor substrate of a first conductivity type, with a first surface arranged with a highly doped surface field layer of the first conductivity type. The substrate has on the highly doped surface field layer at least one contacting area for contacting the surface field layer with a respective contact. In the first surface at the location of the at least one contacting area a doping concentration in the highly doped surface field layer is increased relative to the doping concentration in the surface area outside the first contacting area, and in the first surface at the location of each contacting area the highly doped surface field layer has a profile depth that is larger than a profile depth of the doped surface field layer outside the contacting area.

### FIELD OF THE INVENTION

The present invention relates to a photovoltaic cell according to the preamble of claim 1. Additionally, the invention relates to a method for manufacturing of such a photovoltaic cell.

### BACKGROUND

From the prior art photovoltaic cells or solar cells are known that are based on a semiconductor substrate that has a p-type or n-type base doping. The semiconductor substrate has a first surface that comprises a highly doped region of the same doping type as the substrate. This highly doped region acts as a surface field and is commonly called a ‘back surface field’ (BSF). The semiconductor substrate has a second surface opposite to the first surface. On the first surface comprising the back surface field contacts are arranged for collecting at least one type of charge carriers, these contacts are located on the back surface field to collect the majority carriers.

A high doped region of the second, opposite, doping type as the substrate is formed to create a p-n junction. The high doped region of the second, opposite, doping type is commonly called the emitter. The emitter area can be formed on the second surface, or adjacent to the back surface field on the first surface. On the emitter area contacts are arranged for collecting the minority charge carriers. By exposing the semiconductor to light, majority and minority charge carriers (electrons and holes) are created that are subsequently separated by the p-n-junction and can be collected at the contacts on the emitter and BSF areas.

Manufacturing of the photovoltaic cell on a n-type silicon substrate can involve a n-type phosphor diffusion e.g., using POCl₃ as precursor for the creation of the highly doped region, which results in a n+ back surface field (BSF) layer. After this step, a p-type diffusion can be done by a p-type dopant such as boron diffusion e.g., using BBr3 as precursor to create a p+ emitter. Other dopant precursors or sources can be used and will be known to the skilled reader.

Because the p+ boron emitter is in this case diffused after the n+ phosphor doping and involves a high temperature step, the phosphor-doping is driven in creating a back surface field region with a thickness that may be between 500 and 1500 nm. This thickness or depth is orthogonal to the first surface, and typically results in back surface field sheet resistance values between 15 and 35 Ω/sq as measured on the back surface field area.

The positive features of such a thick/deep back surface field are 1) improved conduction of the majority carriers, 2) shielding/repelling of the minority carriers and 3) attraction of majority carriers. Properties 2 and 3 result in an accumulation layer, where the product of majority and minority concentration at the surface is lower than in the bulk which results in a decreased surface recombination rate.

The negative features of a deep back surface field are 1) a high Auger recombination due to high carrier concentration, 2) free carrier absorption due to high carrier concentration and 3) a high surface recombination velocity for the minority carriers.

Furthermore, since the boron emitter diffusion is executed after the phosphorous BSF diffusion this step leaves a parasitic p+ doped layer of about 5-60 nm on top of the back surface field layer, further increasing the recombination. This parasitic p+ boron doped layer is in most cases not homogeneous, and can differ in depth over the BSF area. As a combined result of the parasitic boron diffusion, and of the negative features 1-3, the efficiency of the photovoltaic cell is adversely affected.

The presence of parasitic B-diffusion in combination with highly doped and deep BSF makes an edge isolation step compulsory during the cell manufacture process which can have significant cost impact.

It is an object of the present invention to provide a photovoltaic cell and a method for manufacturing such a photovoltaic cell that overcome or mitigate the above detrimental effects.

### SUMMARY OF THE INVENTION

The above object is achieved by a photovoltaic cell comprising a semiconductor substrate of a first conductivity type, with a first surface arranged with a highly doped surface field layer of the first conductivity type; the substrate having on the highly doped surface field layer at least one contacting area for contacting the surface field layer with a respective contact, wherein in the first surface at the location of said at least one contacting area a doping concentration in the highly doped surface field layer is increased relative to the doping concentration in the surface area outside the first contacting area,

and in the first surface at the location of each contacting area the highly doped surface field layer has a profile depth that is larger than a profile depth of the doped surface field layer outside the contacting area
wherein the highly doped surface field layer outside the first contacting areas includes an edge portion at the circumference of the semiconductor substrate and the highly doped surface field layer outside the first contacting areas including the edge portion is arranged to be locally thinner relative to the surface field layer in the first surface at the location of the first contacting areas.

In such a photovoltaic cell the negative effects of the highly doped surface field are reduced due to the above modification of the surface field area. The photovoltaic cell, also called solar cell, is made of a semiconductor substrate (i.e., n-type). The semiconductor substrate has a first surface that comprises a higher doped back surface field region of the same doping type as the substrate (i.e., n++BSF made by i.e. phosphorous diffusion). On this first surface comprising the back surface field contacts are arranged for collecting at least one type of charge carriers. The contacts are located on a first contact area or on multiple contact areas and are conductively coupled to the back surface field layer. The back surface field in this first contacting area is higher doped compared to the area of the first surface around it, with a higher peak doping concentration and a deeper back surface field profile. Furthermore, the first contacting area itself is elevated compared to the area around it.

The invention provides that a reduced peak doping concentration and reduced depth of the n++ phosphorous doping in the back surface field layer outside the first contacting area is obtained by removal of the top portion of this said back surface field layer. Advantageously, the surface doping concentration is reduced as well and in case a parasitic emitter of the other doping type (i.e., p++ boron emitter) was formed on top of the high doped back surface field layer by a subsequent emitter diffusion (using i.e., boron diffusion), this layer of parasitic emitter dopants is also removed. Moreover, since the removal of the back surface field layer extends in the areas outside the contacting areas, the photovoltaic cell is directly provided with an edge portion with relatively high resistance and improved edge isolation.

In this manner, in the back surface field layer outside the first contacting area the negative effects of a highly doped back surface field as mentioned in the background (high surface recombination velocity, free carrier absorption and Auger recombination) are reduced.

Additionally, other surface recombination effects are reduced as well by the lower phosphor doping and absence of parasitic boron at the surface.

Because the back surface field in the contact area(s) is still highly doped, the positive properties as mentioned in the background (improved conduction of the majority carriers, shielding/repelling of the minority carriers and attraction of majority carriers) are maintained below the contacts. In this way, the conductive properties of the back surface field contacting can still be maintained at a high level, while also the recombination that may occur below the metal-silicon contact interface is reduced by enhanced shielding of the minority carriers.

As a result, the back surface field is optimized for both the contacting area and the area outside the contacting area, the internal losses in the photovoltaic cell are decreased and the solar cell's efficiency improves.

The contacting area may be larger than the area below the actual metal contacts in order to achieve better compatibility with the resolution of the metal printing process. The actual contact can be metallic lines, also called fingers, and may have a width between 30-500 μm and the highly doped areas might range from 80-800 μm, respectively.

According to an aspect, the present invention relates to a photovoltaic cell as described above, wherein the doping concentration is either a surface doping concentration or a peak doping concentration.

According to an aspect, the present invention relates to a photovoltaic cell as described above, wherein the profile depth of the doped surface field layer outside the contacting area is non-zero.

According to an aspect the present invention relates to a photovoltaic cell as described above, wherein the peak doping concentration in the first contacting area is between about 5×10¹⁹ atoms/cm³ and 5×10²⁰ atoms/cm³, preferably at least 1×10²⁰ atoms/cm³ and the peak doping concentration outside the first contacting area is less than 1×10²⁰ atoms/cm³, preferably between about 1×10¹⁹ atoms/cm³ and about 6×10¹⁹ atoms/cm³, or even less than about 1×10¹⁹ atoms/cm³. These values can be measured with, for instance, the ECV or the SIMS method and will be known to the skilled reader.

According to an aspect, the present invention relates to a photovoltaic cell as described above, wherein the surface of the surface field layer outside the contacting area is recessed compared to the surface of the at least one contacting area of the first surface.

Outside the first contacting area(s), top part of the back surface field has been removed creating a recessed area within the first surface area.

According to an aspect the present invention relates to a photovoltaic cell as described above, wherein the profile depth of the surface field layer modulates between a first depth t1 under the first contacting area and a second non-zero depth t2 outside the first contacting area, wherein the first depth is larger than the second depth; the peak doping concentration of the surface field layer modulating accordingly, with a first concentration profile C1 corresponding to the first depth t1 and a second concentration C2 corresponding to the second depth t2 where C1 is larger than C2.

According to an aspect the present invention relates to a photovoltaic cell as described above, wherein a difference between the first depth t1 and the second depth t2 is at least 50 nm.

According to an aspect the present invention relates to a photovoltaic cell as described above, wherein the first depth is between about 500 and about 1500 nm, and a difference between the first depth and the second depth is between 50 and about 500 nm.

According to an aspect the present invention relates to a photovoltaic cell as described above, wherein a recess in the surface field layer outside the contacting area is equal to the difference between the first and second depths.

According to an aspect the present invention relates to a photovoltaic cell as described above, wherein in the edge region at a circumference of the substrate, the surface of the surface field layer outside the contacting area is recessed compared to the surface of the at least one contacting area of the first surface; the recess depth being at least 50 nm, preferably more than 300 nm.

According to an aspect the present invention relates to a photovoltaic cell as described above, wherein the first conductivity type is n-type and the second conductivity type is p-type.

According to an aspect the present invention relates to a photovoltaic cell as described above, wherein a doping element for the highly doped back surface field layer comprises phosphor, and a second doping element of the second, opposite, conductivity type comprises boron.

According to an aspect the present invention relates to a photovoltaic cell as described above, wherein a parasitic doping of a second doping type, opposite to the first conductivity type, is present at the at least one contacting area.

Also, the present invention relates to a method for manufacturing a photovoltaic cell based on a semiconductor substrate of a first conductivity type, the substrate comprising a first surface that comprises a surface field layer and a second surface opposite the first surface, wherein the method comprises:

creating a highly doped surface field layer of the first conductivity type on the first surface;
patterning on the highly doped surface field layer first contacting areas for one or more contact areas,
wherein the patterning comprises a local thinning of the highly doped surface field layer outside the first contacting areas including an edge portion at the circumference of the semiconductor substrate relative to the highly doped surface layer in the first contacting areas to create in the first surface at the location of the first contacting area a surface doping concentration and a peak doping concentration and thickness of the highly doped surface field layer that are larger relative to the surface doping concentration and the peak doping concentration in the surface area outside the first contacting area including the edge portion at the circumference of the semiconductor substrate,
and to create in the first surface at the location of each contacting area a profile depth of the highly doped surface layer that is larger than a profile depth of the doped surface field layer outside the contacting area;
wherein the local thinning creates the recessed surface in the first surface outside the contacting area including the edge portion at the circumference of the semiconductor substrate,
and a step of edge isolation is omitted after forming the emitter layer on the second surface of the substrate when the condition is fulfilled that a resistance value in the edge portion is equal to or larger than a predetermined minimum value of the edge resistance

Provided the conductivity in the recessed area is reduced sufficiently an edge isolation step could therefore be omitted.

According to an aspect, there is provided a method as described above, wherein the edge resistance is defined by R_{edge}=Rₛₕₑₑₜ×d/w for a given ratio of a width d of the recessed surface in the edge portion and a width w of the contacting area is equal to or larger than the minimum value; Rₛₕₑₑₜ being a sheet resistance value measured in the edge portion.

According to an aspect, there is provided a method as described above, wherein the predetermined minimum value of R_{edge} is minimally 100 Ohms.

Preferably, in an embodiment, the recessed surface in the edge region has an edge resistance of about 100 Ohms or higher.

According to an aspect, there is provided a method as described above, wherein the solar cell comprises a patterned finger-shaped first contacting area with N terminals at the edge of the substrate, the fingers having a width t with a distance L between terminal and edge of the substrate, the edge having a sheet resistance Rsh, under the condition that an edge resistance Rq on the edge of the substrate has a minimum value R0, the relation between distance L, width t and edge resistance R0 being given by

$$\frac{{R}_{sh} L}{N ( B - t )} ln ( \frac{B}{t} ) > R 0$$

with B being a fractional length of an edge portion adjacent to an end of each terminal, along the edge of the substrate.

According to an aspect, there is provided a method as described above, wherein R0 is at least 10 Ohms or larger.

Preferably, the recessed surface in the edge region has an edge resistance of about 10 Ohms or higher.

According to an aspect, there is provided a method as described above, wherein the local thinning creates a recessed surface within the first surface area outside the first contacting area.

According to an aspect, there is provided a method as described above, wherein the recessed surface is created in an edge region of the semiconductor substrate.

According to an aspect, there is provided a method as described above, wherein a parasitic doping of a second doping type, opposite to the first conductivity type, is removed from the doped surface field layer outside the first contacting area, and is still present at the contacting area.

According to an aspect, there is provided a method as described above, wherein the local thinning is done by using an etching paste applied on the back surface field layer outside the first contacting areas.

According to an aspect, there is provided a method as described above, wherein the local thinning comprises:

providing an etching mask layer on the surface field layer;
patterning the etching mask layer to expose an area of the surface field layer outside the first contacting areas;
etching the exposed area of the surface field layer.

According to an aspect, there is provided a method as described above for a photovoltaic cell as described above, wherein the creation of the highly doped surface field layer comprises creating a phosphor doped layer in the first surface by diffusion from a phosphor containing source layer.

According to an aspect, there is provided a method as described above, further comprising:

after said creating a phosphor doped layer in the first surface, subsequently creating an emitter layer in either the second surface or in portions of the first surface by diffusion from a boron containing source layer.

According to an aspect, there is provided a method as described above, wherein the local thinning is carried out after diffusion of the phosphor and boron and after the removal of the phosphor containing source layer and boron containing source layer.

Advantageous embodiments are further defined by the dependent claims.

### BRIEF DESCRIPTION OF DRAWINGS

The invention will be explained in more detail below with reference to drawings in which illustrative embodiments thereof are shown. They are intended exclusively for illustrative purposes and not to restrict the inventive concept, which is defined by the appended claims.

FIG. 1 shows a cross-sectional view of a photovoltaic cell with a back surface field layer according to the prior art;

FIGS. 2a and 2b show cross-sectional views of a photovoltaic cell according to an embodiment of the invention;

FIGS. 3a and 3b show a cross-sectional of a photovoltaic cell according to embodiments of the invention;

FIG. 4 shows a dopant concentration profile for a photovoltaic cell according to an embodiment and a photovoltaic cell according to the prior art; measured by ECV method;

FIG. 5a, 5b show a process flow for a method in accordance with an embodiment of the invention;

FIGS. 6a, 6b show a plane view of a solar cell in accordance with the present invention, and

FIGS. 7a, 7b show a plane view of a solar cell in accordance with the present invention.

### DETAILED DESCRIPTION OF EMBODIMENTS

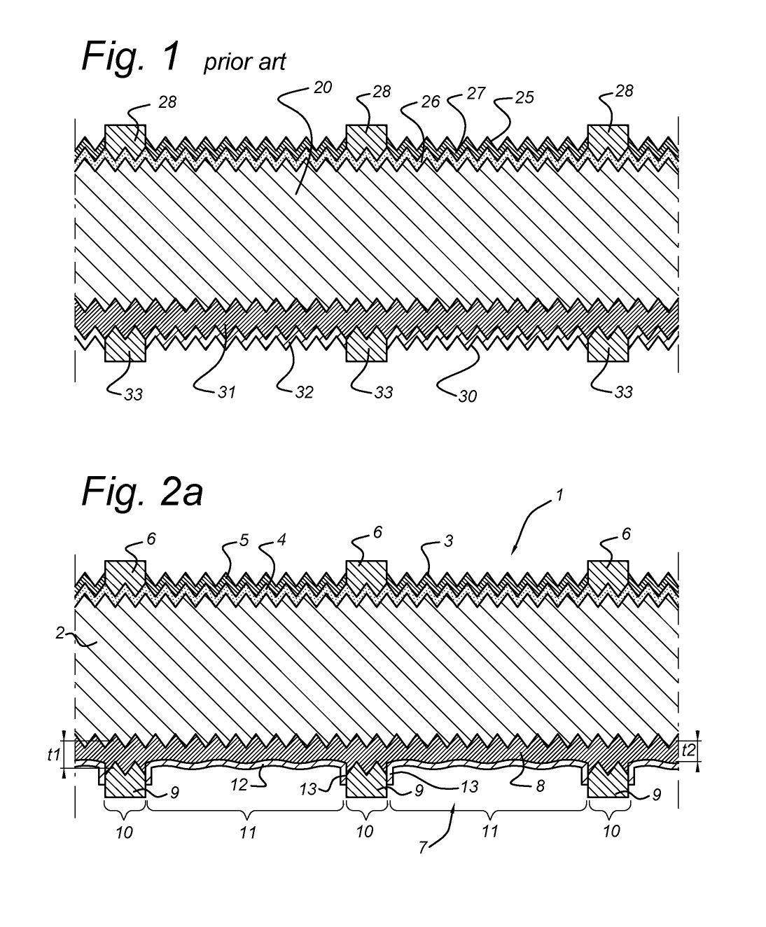

FIG. 1 shows a cross-sectional view of a photovoltaic cell with a back surface field layer according to the prior art.

The prior art photovoltaic cell comprises a semiconductor substrate 20 of a first conductivity type, e.g., n-type. The substrate 20 has a front surface 25 and a rear surface 30. The front surface 25 is directed, during use, towards a radiation source such as the Sun, for collecting radiation energy.

The front surface 25 further comprises an emitter layer 26 of second, opposite, conductivity type (e.g., p-type) and a front passivating and anti-reflective coating layer 27.

The rear surface 30 of the substrate is provided with a highly doped back surface field layer 31 comprising a high concentration of first conductivity type dopant (n-type: e.g., Phosphor). The back surface field layer 31 has a substantially constant thickness (also called depth) over the photoactive area of the photovoltaic cell.

Further, the back surface field layer 31 is covered with a rear passivating and anti-reflective or internal-reflective coating 32.

At least the front surface 25 may have been processed with a surface treatment to obtain texture in the front surface. The rear surface 30 may be smoothened or polished, but may also be textured. As will be appreciated by the skilled in the art, the texturing of the rear surface depends on the actual solar cell type.

In this example, the photovoltaic cell 20 of the prior art maybe a conventional H-cell that comprises front electrodes 28 and rear electrodes 33 which can be contacted externally. It is noted different electrode configurations such as MWT, EWT or IBC could be applied in such a prior art photovoltaic cell.

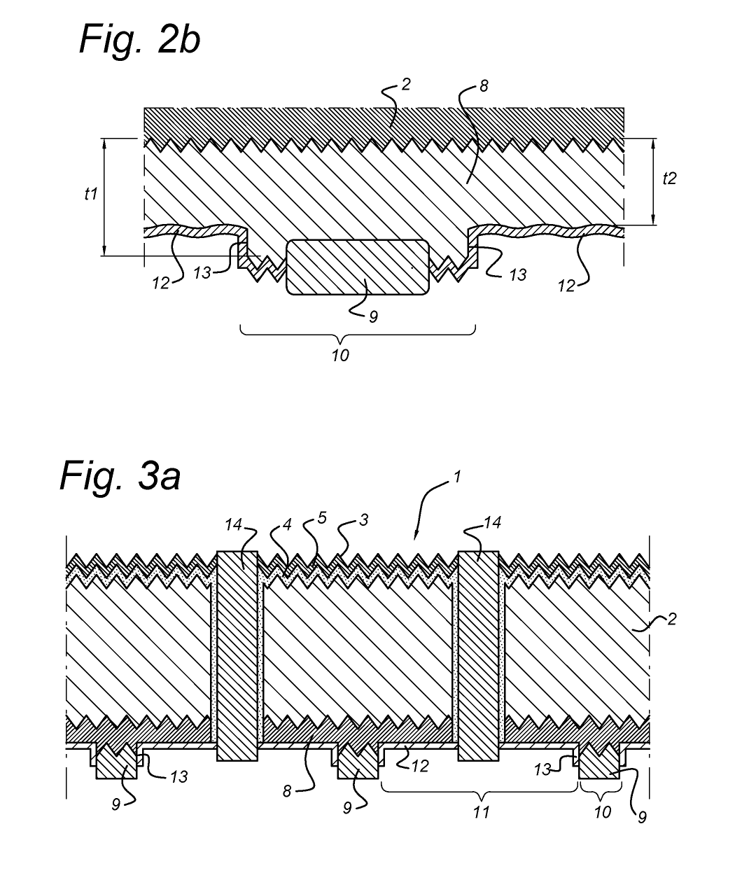

FIG. 2a shows a cross-sectional of a photovoltaic cell 1 according to an embodiment of the invention, in FIG. 2b a part of FIG. 2a is enlarged for clarity.

A photovoltaic cell 1 according to the embodiment of the invention comprises a semiconductor substrate 2 of first conductivity type, e.g., n-type. A front surface 3 of the substrate comprises an emitter layer 4 of second, opposite conductivity type (e.g., p-type) that is covered by a passivating and anti-reflective coating 5. Front contacts 6 to the emitter layer 4 are positioned on the front surface. A rear surface 7 of the substrate 2 comprises a back surface field layer 8 of first conductivity type. On the back surface field layer 8 rear contacts 9 are positioned in first contacting areas 10 of the back surface field layer 8. As can be seen in FIG. 2b, the first contact area 10 may be larger than the area below the actual rear contacts 9. In the first contacting areas 10, the back surface field layer 8 has a first thickness t1. In a remaining area 11 of the back surface field layer 8 outside the first contacting areas 10, the back surface field layer 8 has been thinned to a recessed surface 11 with a second non-zero thickness t2, which is lower than the first thickness t1.

In this manner, at the location of the first contacting areas 10 the highly doped back surface field layer 8 is elevated relative to the recessed surface 11 of the back surface field layer 8 outside or adjacent to the first contacting areas 10.

Advantageously, the phosphor surface doping is reduced and in case a p+ emitter was formed by a subsequent BBr₃ diffusion, according to an embodiment of this invention, the parasitic boron is also removed.

The peak doping concentration (e.g., n++ phosphor) in the recessed surface 11 outside the first contacting areas is reduced to a lower value than the value of the peak doping concentration in the first contacting areas. For example, if the doping concentration of the back surface field profile C1 in the first contacting area 10 is at least 1×10²⁰ atoms/cm³ then the doping concentration of the back surface field profile C2 in the recessed surface adjacent to the first contacting areas is less than 1×10²⁰ atoms/cm³, preferably between about 6×10¹⁸ atoms/cm³ and about 6×10¹⁹ atoms/cm³. These values can be measured with, for instance, the ECV or the SIMS method and will be known to the skilled reader.

The actual difference between t1, C1 and t2, C2 depends on the degree of removal of the back surface field layer 8 of the rear surface 7 outside of the first contacting areas, where t1>t2 and C1>C2. Examples of the back surface field profiles C1 and C2 are shown in FIG. 4. It will be appreciated that the doping concentration profiles C1, C2 relate to a total doping per cross-section.

In this manner, in the back surface field layer 8 outside the first contacting area 10 the free carrier absorption and Auger recombination phenomena are reduced. Additionally, other rear surface recombination effects reduce as well due to the lower phosphor doping at the surface. Additionally, any parasitic doping of the opposite doping type resulting from a second, (p+) emitter diffusion step is removed as well. As a result, the internal losses in the photovoltaic cell 1 decreases and the cell's efficiency improves. At the same time since the first contacting area 10 has a higher surface doping, the contact resistance between the back surface field layer 8 in the first contacting area 10 and the associated rear contact 9 can be maintained at a relatively low level.

According to one embodiment of the invention, the back surface field layer 8 is a continuous layer over the photoactive area of the rear surface 7. The thickness of the back surface field layer 8 modulates between the first thickness t1 under the first contacting areas 10 and the second non-zero thickness t2 in the remaining area 11 adjacent to the first contacting areas 9, with the first thickness t1 being larger than the second thickness t2. The doping concentration of the back surface field modulates simultaneously between the profiles C1 and C2, where the profile C1 exists in areas with thickness t1 and profile C2 exists in areas with thickness t2. See also FIG. 4.

The elevation, i.e., the difference between the first t1 and the second t2 thickness and the difference between the first C1 and second doping profile C2 is dependent on some factors such as a shape of the initial dopant profile C1 in the back surface field layer 8, its maximum concentration and its maximum thickness (the first thickness) and a parasitic doping of the top of the back surface field layer (originating from the creation of the front side emitter layer).

Geometrically, the degree of texture of the rear surface may influence the shape and levels of both the elevated and recessed portions of the rear surface. The rear surface may be polished, smoothened or still slightly textured depending on the processing of the rear surface 7.

In an embodiment, the first thickness t1 is about 1000 nm, say between about 500 and 1500 nm. The parasitic doping has a thickness of about 50 nm, say between 5 and 60 nm. According to an embodiment of the invention, the back surface field layer 8 is locally thinned down in the remaining area outside the first contacting areas 10 with at least the thickness of the parasitic doping layer. The elevation of the first contacting area 10 over the remaining area 11 is thus at least between 5 and 60 nm.

In embodiments where the rear surface 7 is smoothened or textured then the elevation is determined from the average levels of the elevated 10 and recessed portions 11.

In an embodiment, the first thickness is between about 500 and about 1500 nm, and the back surface field layer 8 outside the first contacting areas 10 is thinned to create an elevation difference between the first thickness t1 and the second thickness t2 of between 50 and about 500 nm.

In an embodiment, the first back surface field profile C1 has a peak doping of at least 1×10²⁰ atoms/cm3 in the first contacting areas 10 and as a result of the thinning, the back surface field profile C2 outside the first contacting areas 10 is reduced to a peak doping below 1×10²⁰, preferably below 6×10¹⁹ or even below 1×10¹⁹ atoms/cm³.

The thinning of the back surface field layer 8 outside the first contacting area 10 can be done by an etching process that in a selected area locally reduces the thickness t1 of the back surface field layer 8 to the second thickness t2.

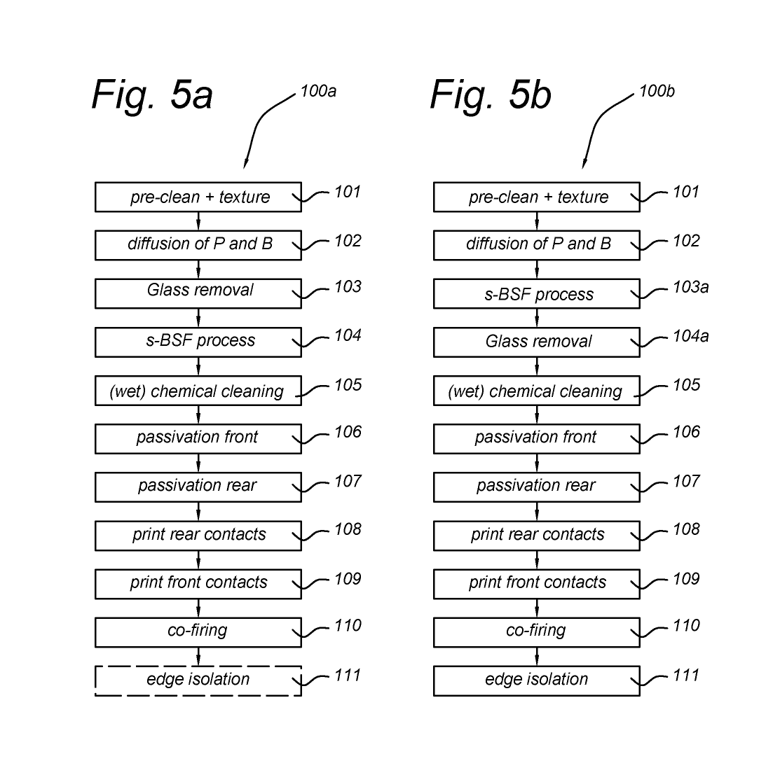

In addition the thinning of the BSF can be performed using a pattern in which the area of the back surface of the semiconductor substrate adjacent to the edges of the substrate is also etched and the difference between t1 and t2 is more than 60 nm, preferably >300 nm. The area adjacent to the cell edge is etched i.e., to obtain a thinned BSF layer at the cell edges with a thickness t2 and profile C2. Then the thickness t2 can be chosen in such a way so as to provide for the edge isolation. As described hereafter with reference to FIG. 5a, an edge isolation process step may be omitted when thinning of the BSF layer is performed at the edges of the solar cell device. Advantageously, the thinning of the BSF with a suitable pattern at the cell's edges may simplify the manufacturing process and reduce costs.

Examples of etching process comprise, but are not limited to, etching by an etching paste that has been applied locally by e.g., a screen print, and etching by using an etching mask that is patterned to expose the back surface field layer outside the first contacting area(s) and subsequent immersing of the samples in an etching agent

The rear surface 7 comprises a rear dielectric layer 12 that covers at least the remaining back surface field layer area outside the first contacting areas 10.

In an embodiment, the rear dielectric layer 12 also comprises portions that cover any side walls 13 of the elevated first contacting areas, and the contacting area 10 outside the actual metal contacts 9 (see also FIG. 2b).

According to an embodiment, the rear surface layer is a passivating and/or (anti-) reflective coating.

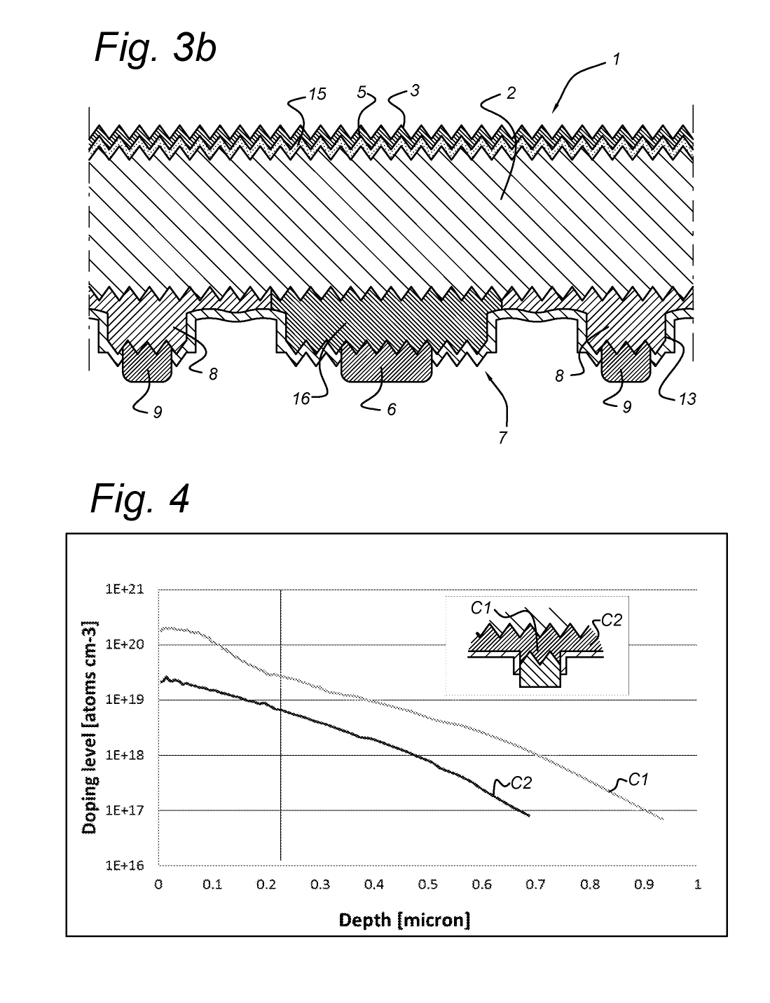

FIG. 3a shows a cross-sectional of a photovoltaic cell according to an embodiment of the invention.

In this embodiment, the photovoltaic cell is configured as a MWT (Metal Wrap Through) solar cell that comprises metallic vias 14 that connect the front surface emitter layer 4 and run through the substrate 2 from the front surface 3 to emitter contacts 8 in the rear surface 7. In this manner, less area of the front surface is utilized required for contacting the emitter layer, thus shadowing of the front surface becomes less.

The emitter contacts are located in the thinned back surface field layer area outside the first contacting areas.

The skilled in the art will appreciate that the present invention can also be implemented in so-called Emitter Wrap Through (EWT) solar cells where vias consist of locally highly doped semiconductor portions extending between the front surface and the rear surface.

FIG. 3b shows a cross-sectional of another photovoltaic cell according to an embodiment of the invention.

In this embodiment, the photovoltaic cell is configured as an IBC (interdigitated back contact) solar cell that comprises of rear side emitter 16 and emitter contacts 6 adjacent to the back surface field 8 on the rear surface 7. The front surface 3 may have a surface field 15 of any dopant type (p+ or n+) or no surface field at all. In this manner, all contacts are removed to the rear surface 7 which eliminates the shading losses.

FIG. 4 shows a dopant concentration profiles for a photovoltaic cell according to an embodiment. Concentration profiles C1, C2 of phosphor in the back surface field layer of an n-type semiconductor substrate are shown that have been formed by POCl3 diffusion and subsequent drive-in during BBr3 diffusion (to produce the emitter layer). Also, in accordance with the present invention the local thinning of the back surface field layer outside the first contacting area has been done.

The dopant concentration profiles C1, C2 are measured using the ECV method.

The inset shows schematically the corresponding locations in the cell for each doping profile C1, C2. A first profile C1 relates to a concentration of phosphor as a function of depth from the rear surface in the back surface field layer of the first contacting area, with the depth corresponding to the back surface field thickness t1. A second profile C2 relates to a concentration of phosphor as a function of depth from the rear surface in the thinned back surface field layer outside the first contacting area, with the depth corresponding to the back surface field thickness t2.

The local thinning of the back surface field layer was about 220 nm. The surface of the second profile C2 at the origin is thus shifted by 220 nm with respect to the first profile C1. A vertical line L is shown at a depth of 220 nm.

It can be observed that the local thinning reduces the doping level from about 2×10²⁰ atoms/cm³ to about 3×10¹⁰ atoms/cm³ at the surface. In correspondence, the sheet resistance increases from about 20 Ω/sq to about 65 Ω/sq. The sheet resistance can be measured for example by 4-point probe method, for example with a Sherescan instrument. As a result, in the thinned back surface field layer outside the first contacting area the recombination effects reduce due to the lower phosphor doping level at the surface, and reduced depth of the phosphor doping. Furthermore, the free carrier absorption reduces due to the reduced depth of the phosphor doping as well. As a result, the internal losses in the photovoltaic cell decrease and the photovoltaic cell's efficiency improves.

FIGS. 5a, 5b show process flows for a method in accordance with an embodiment of the invention.

The method 100a; 100b comprises a number of processing steps to create a photovoltaic cell according to the invention from a semiconductor substrate. Such a substrate can be a silicon polycrystalline or mono-crystalline substrate.

In a preferred embodiment, the substrate is n-type doped.

FIG. 5a shows a process flow 100a according to an embodiment of the invention. In a first processing step 101, the method comprises a pre-cleaning of the substrate and a creation of a texture on at least one of the front and rear surfaces of the substrate.

Next, in a step 102, diffusion of phosphor and boron is done to create the back surface field layer and the emitter layer, respectively. The skilled in the art will recognize that various specific processes and process sequences are available to create the back surface field layer and the emitter layer.

After step 102, in step 103 a glass removal step is carried out in case the diffusion step involved the use of phosphor silicate glass and/or boron silicate glass as diffusion sources.

Next, in step 104, the method comprises the process for an area selective thinning of the back surface field layer such that in the back surface field layer at locations predetermined as first contacting areas for rear contacts, an elevation in the back surface field layer is created.

The process for such local thinning of the back surface field layer in a selected area may involve but is not limited to, etching by an etching paste that has been applied locally by e.g., a screen print, and etching by using an etching mask that is patterned to expose the back surface field layer outside the first contacting area(s).

The etching by etching paste may involve a curing step during which the back surface field layer is etched and a paste removal step.

The etching by a lithographic process using an etching mask involve an application of the etching mask to define which area of the back surface field layer is to be exposed during etching, a dry or wet etching step to etch the back surface field layer, and rinsing and mask removal steps.

In a subsequent step 105, the substrate is chemically cleaned.

Next in step 106 and 107, the rear and front surfaces are covered by a respective passivating (and (anti- or internally) reflective) layer. These two steps 106 and 107 can be executed in arbitrary order.

On the rear surface the passivating layer covers both the elevated first contacting areas and the thinned back surface field layer outside those contacting areas, and the edge in between.

Subsequently, in step 108 rear contacts are created over the rear passivating layer at the locations of the contacting areas. Contacts may be created by e.g., (screen or stencil) printing, jetting, sputtering, evaporation, plating or any other known method.

Then, in step 109, front contacts (or a front contact grid) is created over the passivating layer on the front surface. Again, contacts may be created by e.g., (screen or stencil) printing, jetting, sputtering, evaporation, plating or any other known method. These two steps 108 and 109 can be executed in arbitrary order.

Next, in step 110, the rear and front contacts are co-annealed (co-fired) to create conductive contact to the elevated back surface field layer contacting areas and the front emitter layer, respectively. During co-firing the rear contact material opens the rear passivating layer and contacts the back surface field layer. In a similar manner, the front contact material opens the front passivating layer and contacts the emitter layer. It is noted that alternative methods known in the art for contact formation such as laser contact firing can be used.

Finally, an edge isolation step 111 can be carried out. This edge isolation step can also be performed at any other time after the P- and B-diffusion, for instance between steps 102 and 103, or between steps 105 and 106 or even between steps 104 and 105. Moreover, it will be appreciated that when the thinning of the BSF layer in step 104 is performed using a pattern in which the area adjacent to the edges of the substrate is etched, effectively an edge isolation is created. This requires to obtain a resistance between the edge of the contact area and the cell area that is sufficiently high. This resistance, denoted as the edge resistance is defined as R_{edge}=Rₛₕₑₑₜ×d/w, where Rₛₕₑₑₜ is the sheet resistance of the substrate, d is the distance between cell edge and contact area edge, and w is the width of the terminal of the contact area. For a sufficient edge isolation the edge resistance R_{edge} should be 100Ω or higher.

In case of a sufficiently high edge resistance R_{edge} the separate step 111 of edge isolation may be omitted from the processing steps.

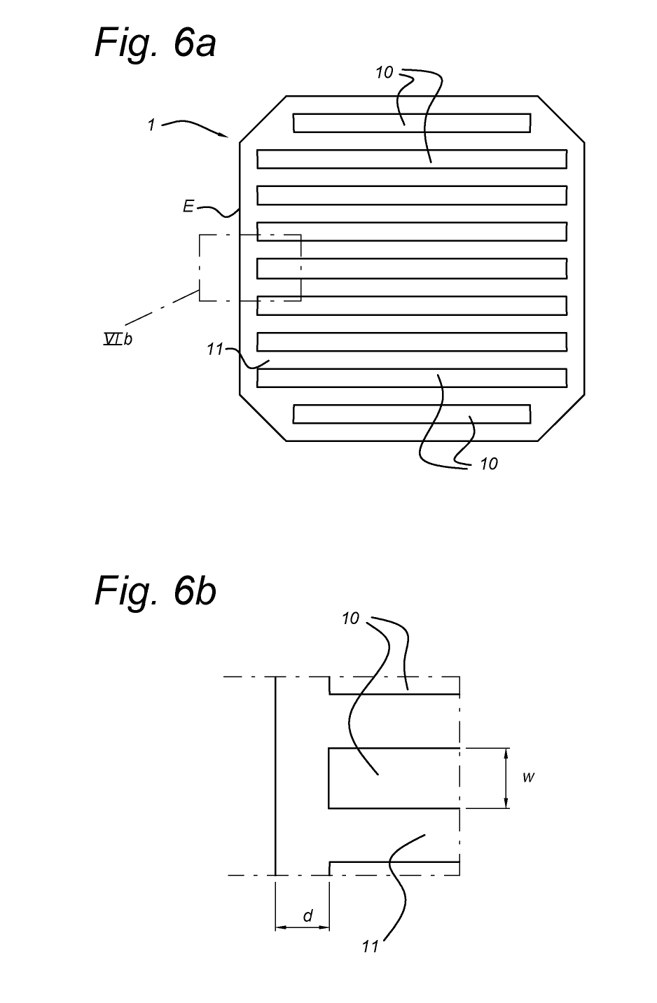

FIGS. 6a and 6b show a plane view of a BSF layer manufactured in accordance with the present invention. The recessed surface portions 11 are arranged in between elongated first contacting areas 10, and extend up to the edges E of the substrate 1. Over a distance d from the edges of the substrate the surface is fully a recessed surface according to the invention. The edge region is void of first contacting areas over distance d. Further, the first contacting areas 10 have a width w.

FIG. 5b shows a process flow 100b according to an embodiment of the invention. Process 100b corresponds closely with the process 100a as described above, except that the process 103a for local thinning of the back surface field layer is carried out before the step 104a in which the glass removal step of the phosphor containing glassy layer and the boron containing glassy layer is carried out. The local thinning removes locally the glassy layer(s) before thinning the back surface field layer.

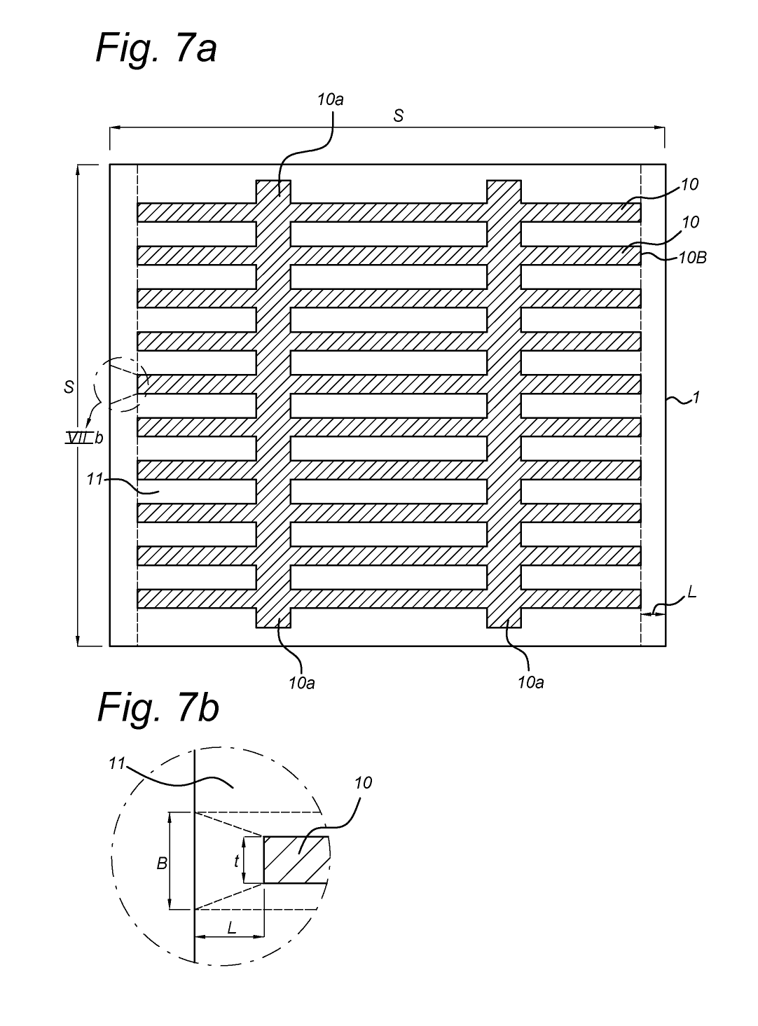

FIGS. 7a, 7b show a plane view of a solar cell in accordance with the present invention. The solar cell is arranged as a so-called H-type cell which has a plurality of parallel contacting fingers 10 that are interconnected by one or more busbars 10a that are arranged perpendicular to the length direction of the fingers.

Each finger extends towards the edges E of the substrate with a terminal portion 10b.

The recessed surface portions 11 where the highly doped surface layer has been (partially or fully) removed, are arranged in between the fingers that comprise the first contacting areas 10 that extend up to the edges E of the substrate 1. Over a perpendicular distance L from the edges of the substrate the surface is fully a recessed surface according to the invention, i.e with the highly doped surface layer substantially removed. Further, the fingers 10 have a width t.

Based on this layout of the solar cell a condition for edge isolation is formulated which is a function of geometry, and sheet resistance Rₛₕ.

The geometry relates to the number N of terminal portions of the fingers, the distance L between edge and terminal 10a, the width t of each terminal (or finger) and a fractional length B equal to the substrate's edge length S per terminal.

In this example B=2S/N.

Accordingly as shown in detail in FIG. 7b, the shunt path from terminal to edge is modeled as a trapezoid area with a top width t, at the end of the terminal 10a and a base width B at the edge of the substrate.

The resistance of a single terminal R_{T} is in this approach is defined as:

$${R}_{T} = \frac{{R}_{sh} L}{B - t} ln ( \frac{B}{t} )$$

The shunt resistance Rq, i.e. the resistance of the shunt path is equal to the resistance at a single terminal divided by the number of terminals N:

R_q=R_T/N Eq.2

A condition for isolation is that the shunt path has a resistance of at least a predetermined value R0. A value of R0 maybe 10Ω:

R_{q}>10Ω Eq.3

This results in:

$$\frac{{R}_{sh} L}{N ( B - t )} ln ( \frac{B}{t} ) > 10 Ω \qquad Eq . 4$$

Thus, the condition can be satisfied for a given sheet resistance by adapting the geometry L, t of N terminals relative to the edge of the substrate.

The skilled in the art will appreciate that in case of a MWT photovoltaic cell the above method may be adapted by a step for creating via holes and a step for creating a conductive path within the via hole.

Likewise, in case of an EWT photovoltaic cell the method will comprise a formation step of highly doped conductive paths through the substrate.

The present invention also relates to a interdigitated back contact (IBC) solar cell and to a method for manufacturing such a solar cell, in which the rear surface comprises an emitter layer of a second conductivity type, adjacent to and interdigitated with the highly doped back surface field layer on the rear surface, and in which in the back surface field layer at the location of the contacting area to the back surface field layer the surface doping concentration is increased relative to the surface doping concentration in the surface area outside the first contacting area.

The present invention also relates to a solar cell which is bifacial, i.e., arranged to receive and capturing solar energy on each surface of the semiconductor substrate.

The skilled in the art will appreciate that the present invention is not limited to photovoltaic cells and methods based on n-type semiconductor substrates, but the invention is also applicable to p-type semiconductor substrates.

In an embodiment of the photovoltaic cell as described above, the surface of the surface field layer is covered by a dielectric layer.

In an embodiment of the photovoltaic cell as described above, the dielectric layer comprises a passivating coating and/or anti-reflective coating and/or an internally reflective coating.

In an embodiment of the photovoltaic cell as described above, the second surface and/or the first surface has a texture.

In an embodiment of the photovoltaic cell as described above, in the at least one contacting area a first metal contact is arranged, the first metal contact being conductively coupled to the surface field layer.

In an embodiment of the photovoltaic cell as described above, the second surface comprises an emitter layer of a second, opposite conductivity type.

In an embodiment of the photovoltaic cell as described above, the first surface comprises an emitter layer of a second, opposite conductivity type adjacent to the surface field layer of the first conductivity type.

In an embodiment of the photovoltaic cell as described above, one or more second metal contacts are arranged on the first contacting areas of the emitter layer that are conductively coupled to the emitter layer.

In an embodiment of the photovoltaic cell as described above, the photovoltaic cell comprises one or more conductive vias between the front and rear surface.

Other alternatives and equivalent embodiments of the present invention are conceivable within the idea of the invention, as will be clear to the person skilled in the art. The scope of the invention is limited only by the appended claims.

1. A photovoltaic cell comprising a semiconductor substrate of a first conductivity type, with a first surface arranged with a highly doped surface field layer of the first conductivity type; the substrate having on the highly doped surface field layer at least one contacting area for contacting the surface field layer with a respective contact,
wherein in the first surface at the location of said at least one contacting area a doping concentration in the highly doped surface field layer is increased relative to the doping concentration in the surface area outside the first contacting area,
and in the first surface at the location of each contacting area the highly doped surface field layer has a profile depth that is larger than a profile depth of the doped surface field layer outside the contacting area wherein the highly doped surface field layer outside the first contacting areas includes an edge portion at the circumference of the semiconductor substrate and the highly doped surface field layer outside the first contacting areas including the edge portion is arranged to be locally thinner relative to the surface field layer in the first surface at the location of the first contacting areas.

2. Photovoltaic cell according to claim 1, wherein the doping concentration is either a surface doping concentration or a peak doping concentration.

3. Photovoltaic cell according to claim 1, where the profile depth of the doped surface field layer outside the contacting area is non-zero.

4. Photovoltaic cell according to claim 1, wherein the peak doping concentration in the first contacting area is between about 5×10¹⁹ atoms/cm³ and 5×10²⁰ atoms/cm³, preferably at least 1×10²⁰ atoms/cm³ and the peak doping concentration outside the first contacting area and in the edge portion at the circumference of the semiconductor substrate is less than 1×10²⁰ atoms/cm³, preferably between about 1×10¹⁹ atoms/cm³ and about 6×10¹⁹ atoms/cm³, or even less than about 1×10¹⁹ atoms/cm³.

5. Photovoltaic cell according to claim 1, wherein the surface of the surface field layer outside the contacting area including the edge portion at the circumference of the semiconductor substrate is recessed compared to the surface of the at least one contacting area of the first surface.

6. Photovoltaic cell according to claim 1, wherein the profile depth of the surface field layer modulates between a first depth t1 under the first contacting area and a second non-zero depth t2 outside the first contacting area including the edge portion at the circumference of the semiconductor substrate, wherein the first depth is larger than the second depth; the peak doping concentration of the surface field layer modulating accordingly, with a first concentration profile C1 corresponding to the first depth t1 and a second concentration C2 corresponding to the second depth t2 where C1 is larger than C2.

7. Photovoltaic cell according to claim 6, wherein a difference between the first depth t1 and the second depth t2 is at least 50 nm.

8. Photovoltaic cell according to claim 6, wherein the surface of the surface field layer outside the contacting area including the edge portion at the circumference of the semiconductor substrate is recessed compared to the surface of the at least one contacting area of the first surface, and wherein the first depth is between about 500 and about 1500 nm, and a difference between the first depth and the second depth is between 50 and about 500 nm.

9. Photovoltaic cell according to claim 7, wherein the surface of the surface field layer outside the contacting area including the edge portion at the circumference of the semiconductor substrate is recessed compared to the surface of the at least one contacting area of the first surface, and wherein the recess depth in the surface field layer outside the contacting area including the edge portion at the circumference of the semiconductor substrate is equal to the difference between the first and second depths.

10. Photovoltaic cell according to claim 1, wherein in the edge region at a circumference of the substrate, the surface of the surface field layer outside the contacting area is recessed compared to the surface of the at least one contacting area of the first surface; the recess depth being at least 50 nm, preferably more than 300 nm.

11. Photovoltaic cell according to claim 1, wherein the first conductivity type is n-type and the second conductivity type is p-type.

12. Photovoltaic cell according to claim 11, wherein a doping element for the highly doped back surface field layer comprises phosphor, and a second doping element of the second, opposite, conductivity type comprises boron.

13. Photovoltaic cell according to claim 1, wherein a parasitic doping of a second doping type, opposite to the first conductivity type, is present at the at least one contacting area.

14. Method for manufacturing a photovoltaic cell based on a semiconductor substrate of a first conductivity type, the substrate comprising a first surface that comprises a surface field layer and a second surface opposite the first surface, wherein the method comprises:
creating a highly doped surface field layer of the first conductivity type on the first surface;
patterning on the highly doped surface field layer first contacting areas for one or more contact areas, wherein the patterning comprises a local thinning of the highly doped surface field layer outside the first contacting areas including an edge portion at the circumference of the semiconductor substrate relative to the highly doped surface layer in the first contacting areas to create in the first surface at the location of the first contacting area a surface doping concentration and a peak doping concentration and thickness of the highly doped surface field layer that are larger relative to the surface doping concentration and the peak doping concentration in the surface area outside the first contacting area including the edge portion at the circumference of the semiconductor substrate,
and to create in the first surface at the location of each contacting area a profile depth of the highly doped surface layer that is larger than a profile depth of the doped surface field layer outside the contacting area;
wherein the local thinning creates the recessed surface in the first surface outside the contacting area including the edge portion at the circumference of the semiconductor substrate,
and a step of edge isolation is omitted after forming the emitter layer on the second surface of the substrate when the condition is fulfilled that a resistance value in the edge portion is equal to or larger than a predetermined minimum value for the edge resistance.

15. Method according to claim 14, wherein the edge resistance is defined by
R_{edge}=Rₛₕₑₑₜ×d/w for a given ratio of a width d of the recessed surface in the edge portion and a width w of the contacting area is equal to or larger than said minimum value; Rₛₕₑₑₜ being a sheet resistance value measured in the edge portion.

16. Method according to claim 15, wherein the value of R_{edge} is minimally 100 Ohms.

17. Method according to claim 14, wherein the photovoltaic cell comprises a patterned finger-shaped first contacting area (10) with N terminals (10b) at the edge of the substrate, the fingers having a width t with a distance L between terminal and edge of the substrate, the edge having a sheet resistance Rsh, under the condition that an edge resistance Rq on the edge of the substrate has a minimum value R0, the relation between distance L, width t and edge resistance Rq being given by
$$Rq = \frac{{R}_{sh} L}{N ( B - t )} ln ( \frac{B}{t} ) > R 0$$
with B being a fractional length of an edge portion adjacent to an end of each terminal, along the edge of the substrate.

18. Method according to claim 17, wherein the value of R0 is at least 10 Ohms or larger.

19. Method according to claim 14, wherein a parasitic doping of a second doping type, opposite to the first conductivity type, is removed from the doped surface field layer outside the first contacting area, and is still present at the contacting area.

20. Method according to claim 14, wherein the local thinning is done by using an etching paste applied on the back surface field layer outside the first contacting areas.

21. Method according to claim 14, wherein the local thinning comprises:
providing an etching mask layer on the surface field layer;
patterning the etching mask layer to expose an area of the surface field layer outside the first contacting areas;
etching the exposed area of the surface field layer.

22. Method according to claim 14, wherein the creation of the highly doped surface field layer comprises creating a phosphor doped layer in the first surface by diffusion from a phosphor containing source layer.

23. Method according to claim 22, further comprising:
after said creating a phosphor doped layer in the first surface, subsequently creating an emitter layer in either the second surface or in portions of the first surface by diffusion from a boron containing source layer.

24. Method according to claim 23, wherein the local thinning is carried out after diffusion of the phosphor and boron and after the removal of the phosphor containing source layer and the boron containing source layer.
